(19) United States
(12) Patent Application Publication
(10) Pub. No.: US 2026/0328861 A1
(43) Pub. Date: Oct. 22, 2026

(54) APPARATUSES, COMPUTER-IMPLEMENTED METHODS, AND COMPUTER PROGRAM PRODUCTS FOR TWO-WAY AUXILIARY POWER UNIT DIAGNOSTICS

(71) Applicant: Honeywell International Inc., Charlotte, NC (US)

(72) Inventors: Rajeev Mohan, Bangalore (IN); Sudhir A Hebbar, Bangalore (IN); Heiner Bruns, Raunheim (DE); Kuchipudi Vamsi Krishna, Hyderabad (IN)

(21) Appl. No.: 19/231,078

(22) Filed: Jun. 6, 2025

(30) Foreign Application Priority Data
Apr. 17, 2025 (IN) 202511037287

(51) Int. Cl. G01R 31/40; G16Y 10/40; G16Y 40/20

(52) U.S. Cl. CPC G01R 31/40; G16Y 40/20; G16Y 10/40

(57) ABSTRACT

Embodiments of the disclosure provide a system for two-way auxiliary power unit analysis comprising an auxiliary power unit electric control unit configured to monitor performance of an auxiliary power unit, and provide APU performance metrics. The system further includes a vehicle data gateway system comprising a communication interface configured for data transfer between the VDG system and the APU-ECU, a data aggregator configured to collect data from subsystems of a vehicle, an electronic information management connector configured to enable secure communication between the VDG system and an information management device, a cloud connector configured to enable communication between the VDG system and a cloud system, and a system command module configured to receive commands from external devices, and subsequently invoke an interface of a corresponding auxiliary power unit. The system further includes an edge-to-edge framework configured to facilitate secure communication between the VDG system and the APU-ECU.

### TECHNOLOGICAL FIELD

Embodiments of the present disclosure are generally directed to systems and methods for two-way auxiliary power unit (APU) diagnostics and trend monitoring.

### BACKGROUND

Auxiliary power units (APUs) are critical components in vehicles (such as aircraft) that perform several functions when main engines are not running. APUs may provide a ground power supply, generating electricity for a vehicle during boarding operations and pre-travel preparations. Such a ground power supply allows systems such as lighting, avionics, air-conditioning, and the like to function without relying on external ground power units or the main engines. APUs may additionally provide the necessary power to start the main engines. For example, an APU servicing an aircraft may supply compressed air to the engines air turbine starters, enabling the spin up of engines to the necessary speed for ignition and self-sustaining speed. In the event of an emergency during travel, the APU can supply electrical power, and, in the case of an aircraft, bleed air if the main engines fail. By handling such tasks, APUs reduce wear and tear on the main engines.

Applicant has discovered various technical problems associated with real-time APU diagnostic capabilities. Through applied effort, ingenuity, and innovation, Applicant has solved many of these identified problems by developing the embodiments of the present disclosure, which are described in detail below.

### BRIEF SUMMARY

In accordance with a first aspect of the disclosure, a system for two-way auxiliary power unit analysis is disclosed, the system comprising an auxiliary power unit electronic control unit (APU-ECU) configured to monitor performance of an auxiliary power unit, and provide a set of auxiliary power unit performance metrics. In at least some embodiments, the system further includes a vehicle data gateway (VDG) system. The VDG system in some embodiments includes a communication interface configured for data transfer between the VDG system and the APU-ECU. In at least some embodiments, the VDG system includes a data aggregator configured to collect data from subsystems of a subject vehicle and prepare said data for one or more intended uses. The VDG system in some embodiments includes an electronic information management connector configured to enable secure communication between the VDG system and an electronic information management device for the subject vehicle. In at least some embodiments, the VDG system includes a cloud connector configured to enable secure communication between the VDG system and a cloud system via a secured connection. The VDG system in some embodiments includes a system command module configured to receive and interpret commands from one or more external devices, and subsequently invoke an interface of a corresponding auxiliary power unit. In at least some embodiments, the system further includes an edge-to-edge framework configured to facilitate secure communication between the VDG system and the APU-ECU, wherein the edge-to-edge framework provides details about resident software modules, communication protocols, and security provisions between the APU-ECU and the VDG system.

In at least some embodiments of the present disclosure, the data aggregator is configured to aggregate data for transmission to one or more external systems.

In at least some embodiments of the present disclosure, the edge-to-edge framework defines a framework comprising software connectors and software gateway applications whose orientation is primarily defined by a direction of data streaming.

In at least some embodiments of the present disclosure, the system further comprises an auxiliary power unit (APU) analytics module configured for performing data analytics on input data received from the auxiliary power unit.

In at least some embodiments of the present disclosure, the APU analytics module is configured to use one or more predictive models for predictive trend monitoring and diagnostics to troubleshoot and diagnose APU errors.

In at least some embodiments of the present disclosure, the APU analytics module is configured to continuously train the one or more predictive models based on data received from the auxiliary power unit.

In at least some embodiments of the present disclosure, the system further comprises an analytics portal comprising a visual dashboard application providing graphical details of parameter trending.

In at least some embodiments of the present disclosure, the APU-ECU is configured to receive a message intended for a first edge node, send the message to the first edge node, determine if the first edge node is a gateway node, identify a configured network associated with the first edge node, and send the message to an IoT platform via the configured network.

In at least some embodiments of the present disclosure, the APU-ECU is configured to select a parent node of the first edge node, determine if the parent node of the first edge node is a gateway node, identify a configured network associated with the parent node of the first edge node, and send the message to the IoT platform via the configured network.

In at least some embodiments of the present disclosure, the cloud system comprises an Internet of Things (IoT) platform configured to receive input intended for a subject edge node, determine if the subject edge node is a gateway node, and process the received input.

In at least some embodiments of the present disclosure, the IoT platform is further configured to route the received input to the APU-ECU responsive to determining that the subject edge node is not a gateway node.

In at least some embodiments of the present disclosure, the APU-ECU is further configured to process the received input using the APU-ECU responsive to determining that the subject edge node is not a gateway node.

In accordance with another embodiment of the present disclosure, a computer-implemented method is disclosed. The computer-implemented method includes receiving, by an auxiliary power unit electric control unit (APU-ECU), a message intended for a first edge node. The computer-implemented method further includes sending, by the APU-ECU, the message to the first edge node. The computer-implemented method further includes determining, by the APU-ECU, if the first edge node is a gateway node. The computer-implemented method further includes identifying, by the APU-ECU, a configured network associated with the first edge node responsive to determining that the first edge node is a gateway node. The computer-implemented method further includes transmitting, by the APU-ECU, the message to an Internet of Things (IoT) platform via the configured network.

In at least some embodiments of the present disclosure, the computer-implemented method further includes selecting a parent node of the first edge node responsive to determining that the first edge node is not a gateway node, determining if the parent node of the first edge node is a gateway node, identifying a configured network associated with the parent node of the first edge node, and sending the message to the IoT platform via the configured network.

In at least some embodiments of the present disclosure, the computer-implemented method further includes transmitting, by the IoT platform, the received message to an additional node to which the IoT platform is operably connected.

In at least some embodiments of the present disclosure, the computer-implemented method further includes receiving, by the IoT platform, input intended for a subject edge node, determining, by the IoT platform, if the subject edge node is a gateway node, and transmitting, by the IoT platform and to the subject edge node, the received input.

In at least some embodiments of the present disclosure, the computer-implemented method further includes transmitting, by the IoT platform and to the APU-ECU, the received input responsive to determining that the subject edge node is not a gateway node.

In at least some embodiments of the present disclosure, the computer-implemented method further includes transmitting, by the APU-ECU, the received input to the subject edge node.

In accordance with another aspect of the present disclosure, a computer program product for providing simultaneous vehicle control is provided. The computer program product in some embodiments includes at least one non-transitory computer-readable storage medium having computer program code stored thereon. The computer program code in execution with at least one processor is configured for performing any one of the example computer-implemented methods described herein.

### BRIEF DESCRIPTION OF THE DRAWINGS

Having thus described the embodiments of the disclosure in general terms, reference now will be made to the accompanying drawings, which are not necessarily drawn to scale, and wherein:

FIG. 1 illustrates a block diagram of a network environment that may be specially configured within which embodiments of the present disclosure may operate.

FIG. 2 illustrates a block diagram of an example apparatus that may be specially configured in accordance with at least some example embodiments of the present disclosure.

FIG. 3 illustrates a block diagram of an example APU-ECU configuration in accordance with at least some example embodiments of the present disclosure.

FIG. 4 depicts a functional block diagram of a vehicle data gateway configuration in accordance with at least some example embodiments of the present disclosure.

FIG. 5 depicts a block diagram of an edge-to-edge framework in accordance with at least some example embodiments of the present disclosure.

FIG. 6 illustrates a functional block diagram of a cloud environment in accordance with at least some example embodiments of the present disclosure.

FIG. 7 illustrates a mind map of APU malfunctions in accordance with at least some example embodiments of the present disclosure.

FIG. 8 illustrates an example PTMD dashboard in accordance with at least some example embodiments of the present disclosure.

FIG. 9 illustrates a flowchart depicting a process for managing dataflow from an APU-ECU to a PTMD cloud in accordance with at least some example embodiments of the present disclosure.

FIG. 10 illustrates a flowchart depicting a process for managing dataflow from a PTMD cloud to an APU-ECU in accordance with at least some example embodiments of the present disclosure.

### DETAILED DESCRIPTION

Embodiments of the present disclosure now will be described more fully hereinafter with reference to the accompanying drawings, in which some, but not all, embodiments of the disclosure are shown. Indeed, embodiments of the disclosure may be embodied in many different forms and should not be construed as limited to the embodiments set forth herein, rather, these embodiments are provided so that this disclosure will satisfy applicable legal requirements. Like numbers refer to like elements throughout.

### Overview

When an APU malfunctions prior to travel, a corresponding trip (flight, etc.) may be delayed or canceled, resulting in severe financial costs to the responsible party while also inconveniencing passengers considerably. Apart from costs associated with unscheduled maintenance, regulatory authorities may also impose fines if a scheduled flight is canceled or delayed for more than a certain defined time period, sometimes in the form of compensation which must be paid to each boarding entitled passenger, for example. Further, absent availability of a functioning APU, a vehicle needs to rely on external ground power units (GPUs) to supply electrical power to enable pre-travel checks, boarding, air conditioning, etc. Without a functioning APU, starting a vehicle's main engine(s) can be a complex task, and can often require increased fuel/energy consumption. A failed APU can trigger required procedures for the maintenance personnel to ensure safety and regulatory compliance. All of the above can ultimately lead to a poor passenger experience, along with compromised cabin comfort due to difficulties maintaining cabin temperature and ventilation. As such, there is a need to get real-time APU data analytics and notifications for enabling maintainers to quickly address problems with a malfunctioning APU.

Current APU data processing techniques comprise an electronic control unit (ECU), which may be located separately from an APU, transmitting data periodically to an A/C data bus. Said data may be snapshotted at specific intervals or significant moments, and sent out of a vehicle via physical means or by interacting with other systems that can send the data outside the aircraft (using HF/VHF radios or satellite communication systems, for example). Subsequently, messages are transferred to a datalink service provider configured to transmit the data along to vehicle maintenance personnel/systems. For advanced processing, vehicle maintenance departments send the data to service providers for data analytics to gain insights into the condition of the APU, which may then be provided via an OEM internet portal and email notifications for taking appropriate actions.

Such existing techniques as described above involve a cost incurred per message to datalink service providers (DSPs) for transferring the APU data. Further, such techniques require (i) specialized software for decoding and interpreting ACARS messages received from the DSPs and (ii) dedicated data storage solutions for storing such incoming messages. Further yet, such techniques require that reports comprising basic information (fault codes, for example) be provided to APU maintainers, wherein such reports may not include contextual information regarding fault occurrence or a fault trend over previous flights, for example. By periodically processing incoming APU reports and providing notifications accordingly, a time delay in getting actionable insights to maintenance personnel/systems is introduced, thereby mitigating the ability to provide real-time insights. Existing techniques additionally lack integration capabilities with other systems or applications, such as a mobile application for maintainers, applications or displays for presenting information to pilots, and/or third-party applications or data sources (such as a weather application, for example).

As such, embodiments of the present disclosure provide a system enabling two-way communication channel between a vehicle and a user and/or a cloud analytics system by which real-time notifications regarding APU diagnostics are provided. Such a system improves over existing APU diagnostics systems by enabling real-time analysis, notification, and remediation of detected APU faults/concerns, while also providing integrations with additional applications providing additional data and/or functionality. Techniques as described herein may enable real-time notification of a vehicle operator, via an electronic flight bag device, for example. By minimizing delays associated with these notifications, costly and slow infrastructure operations can be minimized and otherwise optimized. Further yet, techniques as described herein enable period analytics to be performed on cloud systems and provided to a vehicle operator, thereby providing a notification during a non-emergency situation indicating that an APU is operating correctly and/or capable of taking over as necessary during travel. Further yet, techniques as described herein enable integration with third-party data sources to better inform predictive analytics with respect to APU performance. For example, integration with a data source such as a weather application may enable adjustment of an expected APU performance based on specific predicted weather conditions. In general, the systems and techniques as described herein provide APU performance diagnostic capabilities enabling (i) increased timeliness for detecting and addressing faults, and (ii) more accurate performance prediction based on additionally integrated data.

### Definitions

“Vehicle” refers to any apparatus that traverses throughout an environment by any mean of travel. In some contexts, a vehicle transports goods, persons, and/or the like, or traverses itself throughout an environment for any other purpose, by means of air, sea, or land. In some embodiments, a vehicle is ground-based, air-based, water-based, space-based (e.g., outer space or within an orbit of a planetary body, a natural satellite, or artificial satellite), and/or the like. In some embodiments, the vehicle is an aerial vehicle capable of air travel. Non-limiting examples of aerial vehicles include urban air mobility vehicles, drones, helicopters, fully autonomous air vehicles, semi-autonomous air vehicles, airplanes, orbital craft, spacecraft, and/or the like. In some embodiments, the vehicle is piloted by a human operator onboard the vehicle. For example, in an aerial context, the vehicle may be a commercial airliner operated by a flight crew. In some embodiments, the vehicle is remotely controllable such that a remote operator may initiate and direct movement of the vehicle. Additionally, in some embodiments, the vehicle is unmanned. For example, the vehicle may be a powered, aerial vehicle that does not carry a human operator and is piloted by a remote operator using a control station. In some embodiments, the vehicle is an aquatic vehicle capable of surface or subsurface travel through and/or atop a liquid medium (e.g., water, water-ammonia solution, other water mixtures, and/or the like). Non-limiting examples of aquatic vehicles include unmanned underwater vehicles (UUVs), surface watercraft (e.g., boats, jet skis, and/or the like), amphibious watercraft, hovercraft, hydrofoil craft, and/or the like. As used herein, vehicle may refer to vehicles associated with advanced air mobility (AAM).

“Operator application” refers to any application, software, widget, program, or the like enabling a vehicle operator to access one or more features as described herein. In some contexts, an operator application is accessible via a personal device of an operator, such as a tablet, cell phone, laptop, personal computer, electronic flight bag, or the like. Similarly, “maintainer application” refers to any application, software, widget, program, or the like enabling a vehicle maintainer to access one or more features as described herein. The maintainer application may also be accessible via a personal device as described. It should be appreciated that, though the applications are described as separate applications throughout, there are additional embodiments in which the “operator application” and the “maintainer application” as used herein refer to different views of a same application. For example, a single application may be configured to provide information to an operator and to provide information to a maintainer. In such embodiments, the application may be customizable such that an appropriate view is provided based on whether the user is an operator or a maintainer. The application view may be locked by an authorized user or administrator, or may be customizable by the operator and/or the maintainer.

### Example Systems and Apparatuses of the Disclosure

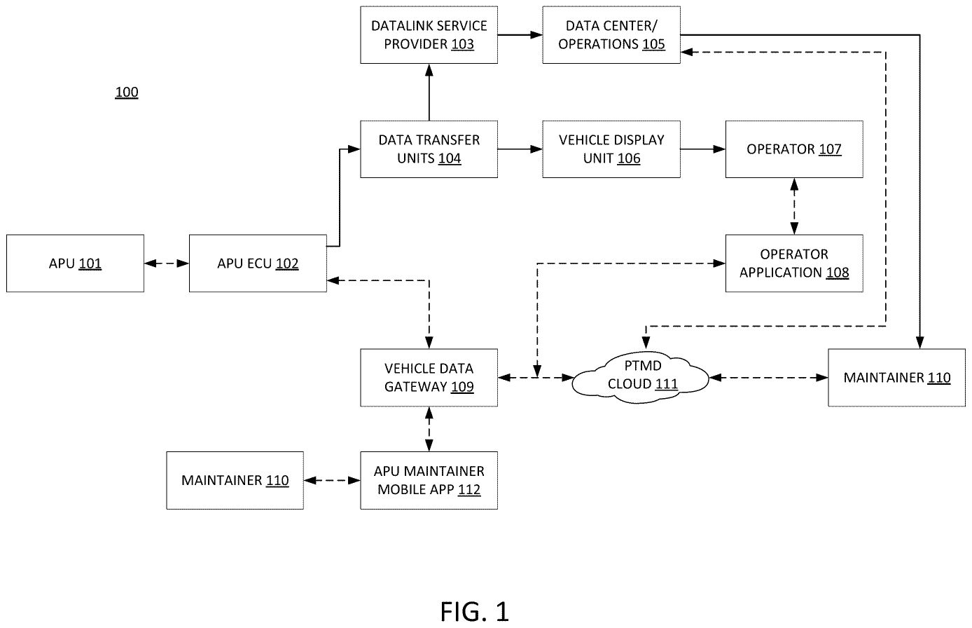

FIG. 1 illustrates a block diagram of a network environment that may be specially configured within which embodiments of the present disclosure may operate. Specifically, FIG. 1 depicts an example networked environment 100. As depicted, networked environment 100 includes an APU 101, an APU-ECU 102, a datalink service provider 103, data transfer units 104, a data center 105, a vehicle display unit 106, an operator 107, an operator application 108, a vehicle data gateway (VDG) 109, a maintainer 110, a PTMD cloud 111, and an APU maintainer application 112. With respect to the dataflow depicted between the various components of networked environment 100, a dotted line depicts bidirectional communication, whereas a solid line depicts unidirectional communication as indicated by the corresponding arrows. In general, networked environment 100 may correspond to a system for APU diagnostics appropriate for executing the techniques as described herein.

In various embodiments, one or more components of the networked environment 100 reside on one or more vehicles (not depicted). The one or more vehicles may include a passenger portion configured to accommodate one or more passengers. For example, the one or more vehicles may include a seating area, cabin, deck, and/or the like that is allocated for holding passengers. In some embodiments, the passenger portion includes one or more computing devices configured to output media elements to one or more passengers. In some embodiments, the computing devices may be handheld devices, seat-mounted devices, wall-mounted devices, ceiling-mounted devices, window-mounted devices, passenger or operator wearable devices, and/or the like. In various embodiments, a computing device may include mobile devices, smartphones, tablets, phablets, kiosks, smart displays, speakers, Internet of Things (IoT) devices, smart appliances, and/or the like. The one or more vehicles may include multiple different computing devices configured to provide various formats of media elements, such as audible media, visual media, tactile media, and/or the like. The one or more vehicles may be referred to throughout as the “subject vehicle.”

APU 101 may be an auxiliary power unit configured to provide energy for starting a vehicle's main engines and providing electricity for other vehicle functions. An APU 101 may consist of a plurality of line replaceable units (LRUs) including, but not limited to, a light switch, an APU fuel line, a generator, an oil filler, a fuel filter, fuel nozzles, an upper shroud, an exhaust muffler, a bleed air manifold, an oil tank, an oil filter, a start motor, a bleed air valve, and the like. Auxiliary power unit electronic control unit 102 (or APU-ECU 102) may be a control unit configured to control and monitor the operation of APU 101. In at least some embodiments, one or more of the LRUs are connected to APU-ECU 102 via one or more electrical interfaces. APU-ECU 102 may be configured to optimize performance of APU 101 by processing data received from the various LRUs of APU 101. APU-ECU 102 may be configured to initiate the APU starting sequence for APU 101, ensuring the engine is properly primed and ignited. APU-ECU 102 may be configured to control the APU's power output, including either of/both of electrical power for vehicle systems or pneumatic power for environmental control. APU-ECU 102 may be configured to monitor APU performance metrics such as, but not limited to, engine speed, temperature, and pressure. In at least some embodiments, APU-ECU 102 is configured to provide notifications or alerts to an operator responsive to detecting a problematic metric.

Datalink service provider 103 (or DSP 103) may be an entity facilitating data communication between vehicles (such as aircraft) and offboard (ground) systems. In at least some embodiments, DSP 103 provides the infrastructure and services necessary for transmitting data between vehicles and offboard systems. DSP 103 may be configured to use technologies such as VHF, satellite, or FANS (Future Air Navigation System) to transmit messages for vehicle operation purposes, such as air traffic control. It should be appreciated that, in certain embodiments wherein real-time communications are enabled via vehicle data gateway 109, communication via DSP 103 may be redundant, but may yet be required to communicate with certain offboard systems. In yet other embodiments, components of networked environment 100 may be configured to communicate entirely without the use of a datalink service provider, and therefore DSP 103 is not included in such environments.

Data transfer units 104 may include one or more devices configured to facilitate transmission of data between a vehicle and an offboard system, often via infrastructure provided by a datalink service provider such as DSP 103. Data transfer units 104 may be configured to act as a bridge converting serial data into IP packets and vice versa, thereby enabling wireless communication of data. Similar to the DSP 103, it should be appreciated that, in certain embodiments wherein real-time communications are enabled via vehicle data gateway 109, communication using the data transfer units 104 may be redundant, but may yet be required to communicate with certain offboard systems. In yet other embodiments, components of networked environment 100 may be configured to communicate entirely without the use of a datalink service provider, and therefore data transfer units 104 are not included in such environments.

Data center 105 may be a data center configured to store data associated with operation of the subject vehicle. In at least some embodiments, data center 105 is configured to store data associated with vehicle performance, including APU performance metrics as determined/monitored by the APU-ECU 102.

Vehicle display unit 106 may include one or more displays on which graphical user interfaces (GUIs), human-machine interfaces (HMIs), and other information related to vehicle operation, APU performance, and/or the like, may be rendered. In some embodiments, the vehicle display unit includes a CRT (cathode ray tube), LCD (liquid crystal display) monitor, LED (light-emitting diode) monitor, and/or the like, for displaying information/data to an operator. In at least some embodiments, vehicle display unit 106 is configured to display a specialized interface configured to execute the operations as described herein.

Operator 107 may be an individual responsible for operating the subject vehicle. For example, in the case where the subject vehicle is an aircraft, operator 107 may be the pilot. In at least some embodiments, such as those wherein multiple users (such as an operator, vehicle staff, offboard staff, and the like) are granted permissions to view information associated with the subject vehicle, operator 107 may refer to these users collectively.

Operator application 108 may include an application available via a personal device (cell phone, tablet, etc.) associated with the operator. In general, operator application 108 is configured to display notifications and/or APU performance data to an operator of the subject vehicle. In at least some embodiments, operator application 108 is configured to further provide operator 107 with one or more remediation actions associated with the APU performance metrics.

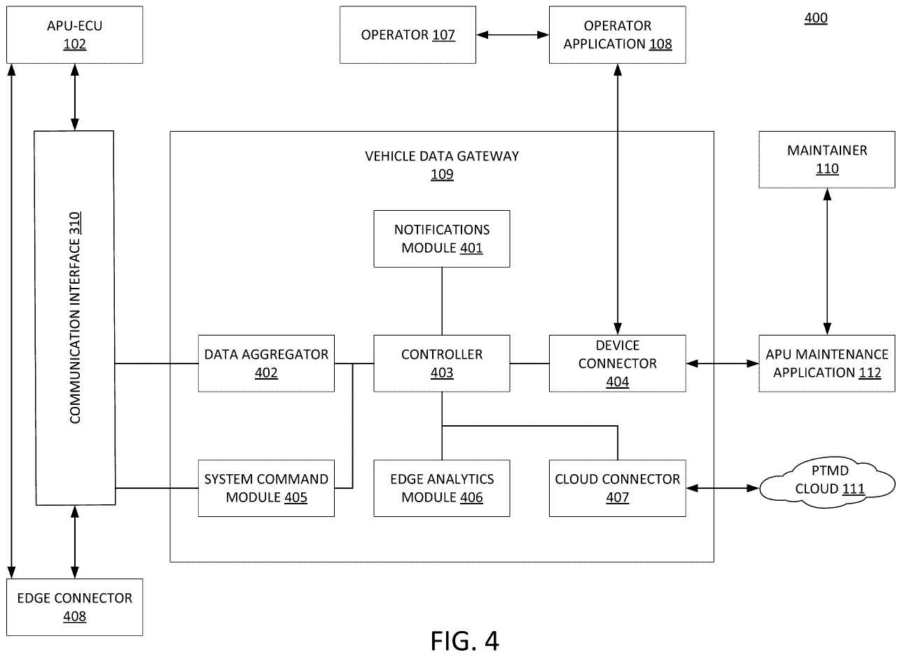

Vehicle data gateway 109 may be configured to enable real-time two-way communication between APU-ECU 102, operator application 108, and PTMD cloud 111. An example arrangement of the vehicle data gateway 109, along with a description of the corresponding function(s), is provided and discussed with respect to FIG. 4.

Maintainer 110 may be a mechanic, maintenance technician, engineer, or other individual responsible for inspecting, repairing, and maintaining vehicles to ensure they are safe for travel. In at least some embodiments, maintainer 110 is representative of a plurality of individuals responsible for vehicle maintenance. In at least some embodiments, maintainer 110 is representative of a system configured to provide information to the individual(s) responsible for maintaining the subject vehicle.

Predictive Trend Monitoring and Diagnostics cloud (PTMD cloud 111) may be a cloud-based application configured to analyze APU performance data to provide condition insights corresponding to APU 101. In at least some embodiments, PTMD cloud 111 is configured to send and receive data to any of vehicle data gateway 109, maintainer 110, operator application 108, and/or data center 105. PTMD cloud 111 may be configured with a machine learning model configured to determine APU 101's condition and/or a predicted future condition of APU 101 based at least in part on historical data corresponding to APU 101 and one or more historically relevant APU measurements for similar APU implementations.

APU maintainer application 112 may be an application available via a personal device (cell phone, tablet, etc.) associated with the maintainer 110. In general APU maintainer application 112 is configured to display notifications and/or APU performance data to a maintainer responsible for the subject vehicle. In at least some embodiments, APU maintainer application 112 is configured to further provide maintainer 110 with one or more remediation actions associated with the APU performance metrics.

Each of the components of the system may be communicatively coupled to transmit data to and/or receive data from one another over the same or different wireless or wired networks. Such configuration(s) include, without limitation, a wired or wireless Personal Area Network (PAN), Local Area Network (LAN), Metropolitan Area Network (MAN), Wide Area Network (WAN), satellite network, radio network, and/or the like. Additionally, while FIG. 1 illustrate certain system entities as separate, standalone entities, the various embodiments are not limited to this particular architecture. In other embodiments, one or more computing entities share one or more components, hardware, and/or the like, or otherwise are embodied by a single computing device such that connection(s) between the computing entities via a network for example are altered and/or rendered unnecessary.

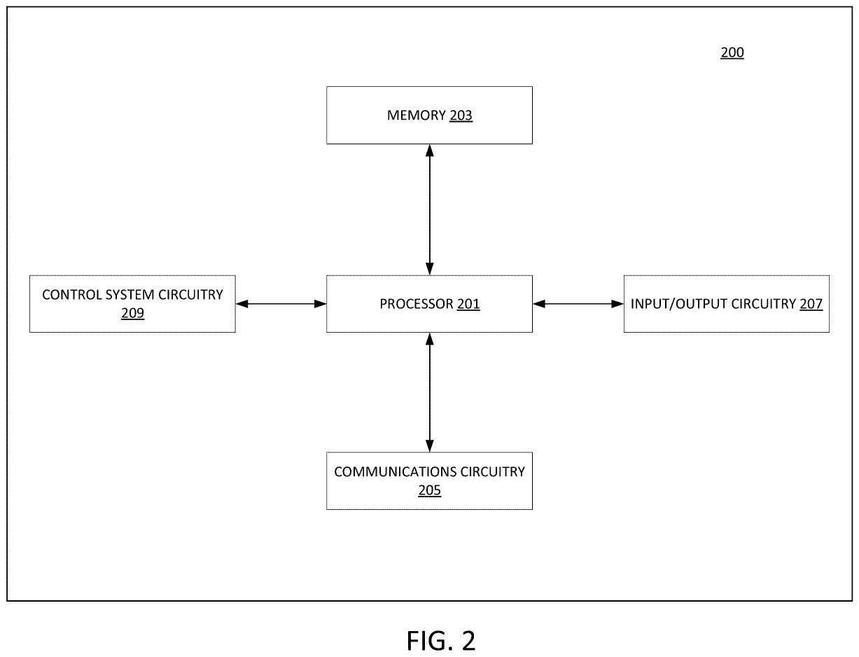

FIG. 2 illustrates a block diagram of an example apparatus 200 that may be specially configured in accordance with at least some example embodiments of the present disclosure. The apparatus 200 may carry out functionality and processes described herein to enable an operator to control multiple vehicles simultaneously. In some embodiments, the apparatus 200 includes a processor 201, memory 203, communications circuitry 205, input/output circuitry 207, and control circuitry 209. In some embodiments, the apparatus 200 is configured, using one or more of the processor 201, memory 203, communications circuitry 205, input/output circuitry 207, and/or control circuitry 209, to execute and perform the operations described herein.

In general, the terms computing entity (or “entity” in reference other than to a user), device, system, and/or similar words used herein interchangeably may refer to, for example, one or more computers, computing entities, desktop computers, mobile phones, tablets, phablets, notebooks, laptops, distributed systems, items/devices, terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Such functions, operations, and/or processes may include, for example, transmitting, receiving, operating on, controlling, modifying, outputting, restoring, processing, displaying, storing, determining, creating/generating, predicting, monitoring, evaluating, comparing, and/or similar terms used herein interchangeably. In one embodiment, these functions, operations, and/or processes may be performed on data, content, information, and/or similar terms used herein interchangeably. In this regard, the apparatus 200 embodies a particular, specially configured computing entity transformed to enable the specific operations described herein and provide the specific advantages associated therewith, as described herein.

Although components are described with respect to functional limitations, it should be understood that the particular implementations necessarily include the use of particular computing hardware. It should also be understood that in some embodiments certain of the components described herein include similar or common hardware. For example, in some embodiments two sets of circuitry both leverage use of the same processor(s), network interface(s), storage medium(s), and/or the like, to perform their associated functions, such that duplicate hardware is not required for each set of circuitry. The use of the term “circuitry” as used herein with respect to components of the apparatuses described herein should therefore be understood to include particular hardware configured to perform the functions associated with the particular circuitry as described herein.

Particularly, the term “circuitry” should be understood broadly to include hardware and, in some embodiments, software for configuring the hardware. For example, in some embodiments, “circuitry” includes processing circuitry, storage media, network interfaces, input/output devices, and/or the like. Additionally, or alternatively, in some embodiments, other elements of the apparatus 200 provide or supplement the functionality of another particular set of circuitry. For example, the processor 201 in some embodiments provides processing functionality to any of the sets of circuitry, the memory 203 provides storage functionality to any of the sets of circuitry, the communications circuitry 205 provides network interface functionality to any of the sets of circuitry, and/or the like.

In some embodiments, the processor 201 (and/or co-processor or any other processing circuitry assisting or otherwise associated with the processor) is/are in communication with the memory 203 via a bus for passing information among components of the apparatus 200. In some embodiments, for example, the memory 203 is non-transitory and may include, for example, one or more volatile and/or non-volatile memories. In other words, for example, the memory 203 in some embodiments includes or embodies an electronic storage device (e.g., a computer readable storage medium). In some embodiments, the memory 203 is configured to store information, data, content, applications, instructions, or the like, for enabling the apparatus 200 to carry out various functions in accordance with example embodiments of the present disclosure (e.g., generating display components, enabling user interactions, and/or the like).

The processor 201 may be embodied in a number of different ways. For example, in some embodiments, the processor 201 includes one or more processing devices configured to perform independently. Additionally, or alternatively, in some embodiments, the processor 201 includes one or more processor(s) configured in tandem via a bus to enable independent execution of instructions, pipelining, and/or multithreading. The use of the terms “processor” and “processing circuitry” should be understood to include a single core processor, a multi-core processor, multiple processors internal to the apparatus 200, and/or one or more remote or “cloud” processor(s) external to the apparatus 200.

In an example embodiment, the processor 201 is configured to execute instructions stored in the memory 203 or otherwise accessible to the processor. Additionally, or alternatively, the processor 201 in some embodiments is configured to execute hard-coded functionality. As such, whether configured by hardware or software methods, or by a combination thereof, the processor 201 represents an entity (e.g., physically embodied in circuitry) capable of performing operations according to an embodiment of the present disclosure while configured accordingly. Additionally, or alternatively, as another example in some example embodiments, when the processor 201 is embodied as an executor of software instructions, the instructions specifically configure the processor 201 to perform the algorithms embodied in the specific operations described herein when such instructions are executed.

As one particular example embodiment, the processor 201 is configured to perform various operations associated with analyzing APU data to diagnose and correct/adjust APU performance. In some embodiments, the processor 201 includes hardware, software, firmware, and/or the like, that obtain APU performance data from the various subsystems of the subject vehicle. For example, the processor 201 may obtain APU performance data from APU-ECU 102. As another example, the processor 201 may obtain weather data from a third-party weather data service. In general, processor 201 may be configured to execute any number of the processes as described herein.

In some embodiments, the apparatus 200 includes input/output circuitry 207 that provides output to a user and, in some embodiments, receives an indication of a user input. In various embodiments, the user is an operator of the subject vehicle, where the operator may be aboard or remote from the subject vehicle. For example, in some contexts, the input/output circuitry 207 provides output to and receives input from one or more operator computing devices, ground station operators, and/or the like. In some embodiments, the input/output circuitry 207 is in communication with the processor 201 to provide such functionality. The input/output circuitry 207 may comprise one or more user interface(s) and in some embodiments includes a display that comprises the interface(s) rendered as a web user interface, an application user interface, a user device, a backend system, or the like. In some embodiments, the input/output circuitry 207 also includes a keyboard, a mouse, a joystick, vehicle controls (e.g., steering, power, braking, and/or the like), a touch screen, touch areas, soft keys a microphone, a speaker, and/or other input/output mechanisms. The processor 201 and/or input/output circuitry 207 comprising the processor may be configured to control one or more functions of one or more user interface elements through computer program instructions (e.g., software and/or firmware) stored on a memory accessible to the processor 201 (e.g., memory 203, and/or the like). In some embodiments, the input/output circuitry 207 includes or utilizes a user-facing application to provide input/output functionality to a display of an operator computing device, passenger computing device, and/or the like.

In some embodiments, the apparatus 200 includes communications circuitry 205. The communications circuitry 205 includes any means such as a device or circuitry embodied in either hardware or a combination of hardware and software that is configured to receive and/or transmit data from/to a network and/or any other device, circuitry, or module in communication with the apparatus 200. In this regard, in some embodiments the communications circuitry 205 includes, for example, a network interface for enabling communications with a wired or wireless communications network. Additionally, or alternatively in some embodiments, the communications circuitry 205 includes one or more network interface card(s), antenna(s), bus(es), switch(es), router(s), modem(s), and supporting hardware, firmware, and/or software, or any other device suitable for enabling communications via one or more communications network(s). Additionally, or alternatively, the communications circuitry 205 includes circuitry for interacting with the antenna(s) and/or other hardware or software to cause transmission of signals via the antenna(s) or to handle receipt of signals received via the antenna(s). In some embodiments, the communications circuitry 205 enables transmission to and/or receipt of data from among the components of networked environment 100 in communication with the apparatus 200.

The control circuitry 209 includes hardware, software, firmware, and/or a combination thereof, that carry out processes for executing APU diagnostics methods as described herein. For example, in some contexts, the control circuitry 209 includes hardware, software, firmware, and/or the like, that process APU data to determine current performance metrics and/or predict future APU performance metrics. In some embodiments, the control circuitry 209 includes a separate processor, specially configured field programmable gate array (FPGA), and/or a specially programmed application specific integrated circuit (ASIC).

Additionally, or alternatively, in some embodiments, two or more of the processor 201, memory 203, communications circuitry 205, input/output circuitry 207, and/or control circuitry 209 are combinable. Additionally, or alternatively, in some embodiments, one or more of the sets of circuitry perform some or all of the functionality described associated with another component. For example, in some embodiments, two or more of the sets of circuitry 201-209 are combined into a single module embodied in hardware, software, firmware, and/or a combination thereof. Similarly, in some embodiments, one or more of the sets of circuitry, for example the memory 203, communications circuitry 205, and/or control circuitry 209 is/are combined with the processor 201, such that the processor 201 performs one or more of the operations described above with respect to each of these sets of circuitry 203-209.

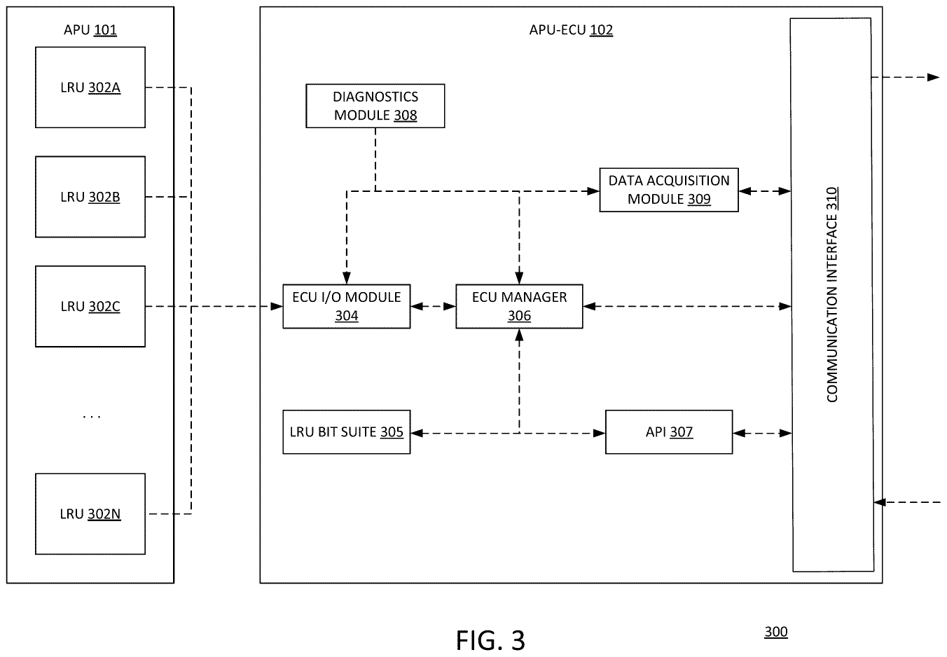

FIG. 3 depicts a functional block diagram of an APU-ECU configuration 300 in accordance with at least some example embodiments of the present disclosure. Notably, FIG. 3 depicts data exchanges between the various components of APU 101 and APU-ECU 102. In general, APU-ECU configuration 300 may enable improved APU diagnostics and predictive analytics, particularly when paired with a vehicle data gateway such as is described with respect to FIG. 4.

As depicted, APU 101 includes a plurality of LRUs 302 (302A, 302B, 302C, . . . 302N). Each LRU 302 is a modular component designed for quick replacement at an operating location to minimize downtime and facilitate rapid return to service. In at least some embodiments, each LRU 302 is a self-contained (sometimes sealed) unit that can be easily removed and replaced without extensive disassembly or specialized tools. In at least some embodiments, one or more of the LRUs 302 may correspond to an APU component which fails to meet the conditions of an LRU component, but provides similar functionality. In general, LRUs 302 represent a plurality of components of an APU 101. The LRUs 302 may be configured to provide date to ECU I/O module 304, include performance metrics corresponding to each LRU 302 and/or overall performance metrics for the APU 101 as a whole. Example LRUs include, but are not limited to, a starter motor, fuel control unit, oil pump and lubrication, bleed air valve, etc.).

As depicted, APU-ECU 102 includes ECU I/O module 304, LRU bit suite 305, ECU manager 306, API 307, diagnostics module 308, data acquisition module 309, and communication interface 310. ECU I/O module 304 may be configured to receive data from the LRUs 302. In at least some embodiments, the received data is raw data requiring conversion into a usable format; in other embodiments, the received data is received in a usable format. In general, ECU I/O module 304 serves as the interface between the LRUs 302 and the APU-ECU 102.

LRU BIT suite 305 may include a set of built in tests that can be run to verify functioning of APU components. In at least some embodiments, LRU BIT suite 305 includes one or more tests corresponding to the LRUs 302, wherein each of the one or more tests is configured to verify proper functioning of one or more features of at least one LRU 302.

ECU manager 306 is configured to manage functioning of the various components of APU-ECU 102. In at least some embodiments, ECU manager 306 communicates with each of ECU I/O module 304, LRU bit suite 305, API 307, diagnostics module 308, data acquisition module 309, and communication interface 310 to ensure each component has access to any data necessary for its intended functions.

API 307 is an application interface configured for performing one or more tasks associated with the various components of APU-ECU 102. For example, API 307 may be configured to run one or more built in tests as indicated by LRU BIT suite 305 responsive to a request. API 307 may be representative of a plurality of APIs configured for executing the various functions associated with operation of the APU-ECU 102.

Diagnostics module 308 is configured to detect operational faults corresponding to the APU 101. In at least some embodiments, diagnostics module 308 is configured to analyze the APU data (including operational data received from the LRUs 302) to determine whether the APU 101 is displaying any faults and/or suboptimal performance based on the metrics. In at least some embodiments, for each performance metric, determining a corresponding fault may include comparing said performance metric to a predetermined baseline/acceptable value, and determining whether the performance metric falls within a defined acceptable threshold of said acceptable value. For any performance metric which fails to fall within the defined acceptable threshold distance of the acceptable value, a likely associated fault may be determined. In at least some embodiments, the determined likely faults are defined and associated with specific metrics, such that a likely fault may be readily identified responsive to an unacceptable/anomalous measurement and/or a combination of such measurements.

Data acquisition module 309 is configured to collect and process data from the other components of APU-ECU 102. In at least some embodiments, data acquisition module 309 is configured to retrieve data from communication interface 310 and diagnostics module 308. Data acquisition module 309 may be further configured to provide a subset of the retrieved data to one or more of diagnostics module 308, ECU manager 306, and communication interface 310. In at least some embodiments, data acquisition module 309 is configured to convert retrieved data into a defined preferred format. In at least some embodiments, data acquisition module 309 is configured to filter and/or validate data before sending it to another component to ensure inputs are within expected ranges. Data acquisition module 309 may further be configured to prepare the retrieved data for further processing.

Communication interface 310 is configured to interact with one or more external systems. For example, communication interface 310 may be configured to interact with a data management unit (DMU) or a central maintenance computer (CMC) on behalf of the APU-ECU 102. In at least some embodiments, communication interface 310 facilitates communication between the APU-ECU 102 and vehicle data gateway 109.

FIG. 4 depicts a functional block diagram of a vehicle data gateway configuration 400 in accordance with at least some example embodiments of the present disclosure. As depicted, the vehicle data gateway configuration 400 includes vehicle data gateway 109, APU-ECU 102, communication interface 410, edge connector 408, operator 107, operator application 108, maintainer 110, APU maintainer application 112, and PTMD cloud 111. Vehicle data gateway configuration 400 enables real-time two-way communication and APU performance diagnostics.

As depicted, vehicle data gateway 109 includes notification module 401, data aggregator 402, controller 403, device connector 404, system command module 405, edge analytics module 406, and cloud connector 407. Notification module 401 may be configured to enable notification messages to be created based on the state of the data transmitted from either APU-ECU 102 or from PTMD cloud 111. Notifications created by notifications module 401 may be provided to the operator 107 via operator application 108, for example, or can be sent to one or more offboard systems.

Data aggregator 402 acts as a hub to collect data from various subsystems of a vehicle, including APU 101. In at least some embodiments, data aggregator 402 is configured to store data for later use or prepare it for transmission to external systems such as PTMD cloud 111. For example, data aggregator 402 may be configured to prepare messages from APU-ECU 102 to be sent as ACARS messages to be transmitted across an IP network to PTMD cloud 111, via which it can be disseminated to consumers offboard.

Controller 403 may be a module configured to enable communication and management of the various components of vehicle data gateway 109. Generally, controller 403 acts as the “brain” of the vehicle data gateway 109.

Device connector 404 may be configured to enable secure communication between the vehicle data gateway 109 and a device hosting operator application 108. In at least some embodiments, device connector 404 uses PKI certificates to ensure secure communications over a Wi-Fi connection. In at least some embodiments, device connector 404 is a part of an edge-to-edge (E2E) communication library. In at least some embodiments, maintainer 110 may additionally connect to APU-ECU 102 via device connector 404 using APU maintainer application 112.

System command module 405 is configured to interpret commands sent from PTMD cloud 111 or the operator application 108 and invoking an appropriate interface (API 602, for example) of the APU-ECU 102. In at least some embodiments, the commands could be used to execute a functionality (e.g., execute specific built in tests), or they could be used to retrieve specific data from APU-ECU 102 and return it to a requester at an offboard system. In at least some embodiments, system command module 405 ensures all safety mechanisms are in place such that erroneous commands are not executed. System command module 405 may be configured to ensure commands are not executed during a specific vehicle operational state if it impacts vehicle safety, for example.

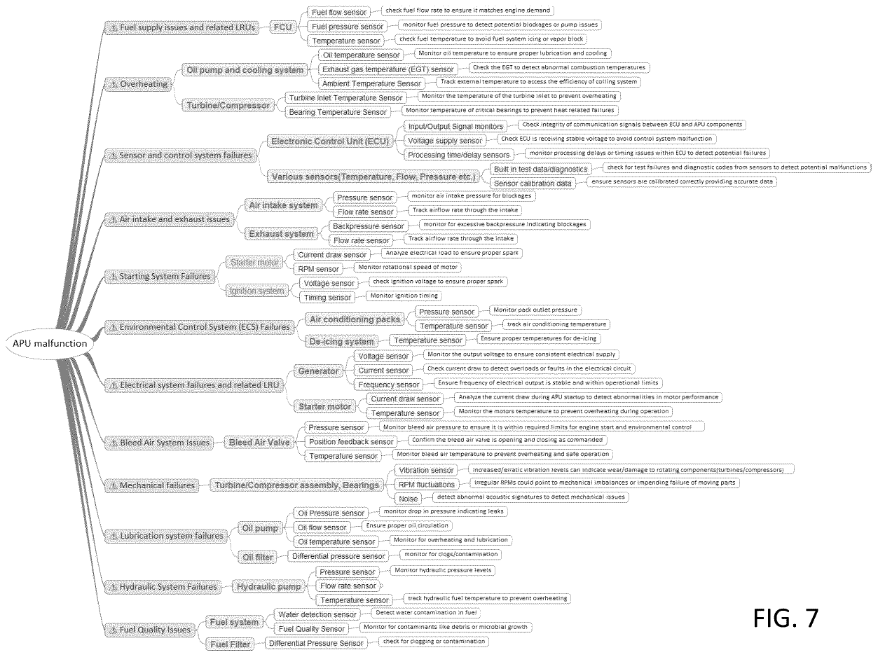

Edge analytics module 406 may be configured to analyze latest data from APU LRUs by syncing data from PTMD cloud 111 as soon as the vehicle and APU-ECU 102 are powered on. In at least some embodiments, edge analytics module 406 is configured to execute a machine learning model that is continuously updated before every vehicle trip based on training on latest data sets with respect to APU 101 and its constituent LRUs. In at least some embodiments, a mind map (such as is depicted with respect to FIG. 7) represents a starting data structure for building a machine learning model for performing edge analytics.

Cloud connector 407 is configured to enable secure communication between vehicle data gateway 109 and PTMD cloud 111 through an IP link. In at least some embodiments, cloud connector 407 is configured to leverage Satcom or Wi-Fi to facilitate secure communication. Cloud connector 407 may be configured to use preconfigured PKI certificates to ensure secure communication, and may connect to the cloud via Internet of Things (IoT) APIs. Cloud connector 407 may be made available via an edge-to-edge (E2E) communication library.

Edge connector 408 is an optional component configured to enable use of an edge connector device for communication. In at least some embodiments, edge connector 408 enables APU-ECU 102 to connect via mechanisms such as Wi-Fi, Bluetooth, ARINC429 channel, and the like. In at least some embodiments, edge connector 408 is configured to securely communicate to vehicle data gateway 109 via an aircraft data bus or via a Wi-Fi interface.

APU-ECU 102 may be configured to optimize performance of APU 101 by processing data received from the various LRUs of APU 101. APU-ECU 102 may be configured to initiate the APU starting sequence for APU 101, ensuring the engine is properly primed and ignited. APU-ECU 102 may be configured to control the APU's power output, including either of/both of electrical power for vehicle systems or pneumatic power for environmental control. APU-ECU 102 may be configured to monitor APU performance metrics such as, but not limited to, engine speed, temperature, and pressure. In at least some embodiments, APU-ECU 102 is configured to provide notifications or alerts to an operator responsive to detecting a problematic metric.

Communication interface 410 is configured to facilitate data transfer via vehicle communication systems from APU-ECU 102 to vehicle data gateway 109. In at least some embodiments, APU-ECU sends data via an aircraft data bus. In some embodiments, APU-ECU 102 can send data via an add-on edge connector device, such as edge connector 408.

Operator 107 may be an individual responsible for operating the subject vehicle. For example, in the case where the subject vehicle is an aircraft, operator 107 may be the pilot. In at least some embodiments, such as those wherein multiple users (such as an operator, vehicle staff, offboard staff, and the like) are granted permissions to view information associated with the subject vehicle, operator 107 may refer to these users collectively.

Operator application 108 may include an application available via a personal device (cell phone, tablet, etc.) associated with the operator. In general, operator application 108 is configured to display notifications and/or APU performance data to an operator of the subject vehicle. In at least some embodiments, operator application 108 is configured to further provide operator 107 with one or more remediation actions associated with the APU performance metrics. In at least some embodiments, operator application 108 corresponds to an electronic flight bag (EFB) device.

Maintainer 110 may be a mechanic, maintenance technician, engineer, or other individual responsible for inspecting, repairing, and maintaining vehicles to ensure they are safe for travel. In at least some embodiments, maintainer 110 is representative of a plurality of individuals responsible for vehicle maintenance. In at least some embodiments, maintainer 110 is representative of a system configured to provide information to the individual(s) responsible for maintaining the subject vehicle.

APU maintainer application 112 may be an application available via a personal device (cell phone, tablet, etc.) associated with the maintainer 110. In general APU maintainer application 112 is configured to display notifications and/or APU performance data to a maintainer responsible for the subject vehicle. In at least some embodiments, APU maintainer application 112 is configured to further provide maintainer 110 with one or more remediation actions associated with the APU performance metrics.

Predictive Trend Monitoring and Diagnostics cloud (PTMD cloud 111) may be a cloud-based application configured to analyze APU performance data to provide condition insights corresponding to a subject APU (such as APU 101). In at least some embodiments, PTMD cloud 111 is configured to send and receive data to any of vehicle data gateway 109, maintainer 110, and operator application 108. PTMD cloud 111 may be configured with a machine learning model configured to determine APU 101's condition and/or a predicted future condition of APU 101 based at least in part on historical data corresponding to APU 101 and one or more historically relevant APU measurements for similar APU implementations.

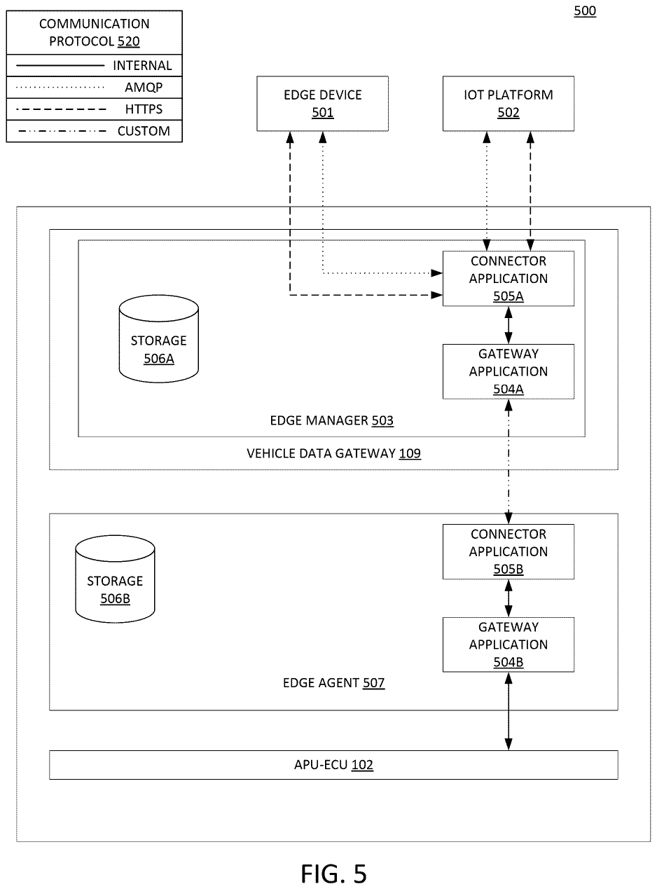

FIG. 5 depicts a block diagram of an edge-to-edge framework 500 in accordance with at least some example embodiments of the present disclosure. Edge framework 500 may enable communication between an edge node, a gateway, a cloud system and a mobile application. Notably, edge framework 500 depicts a communication protocol legend 520 indicating defined protocols enabling communication between components of different types.

The underlying communication between vehicle data gateway 109 and APU-ECU 102 is facilitated by an edge-to-edge (E2E) library. The E2E framework provides details about resident software modules, communication protocols, and security provisions between a vehicle communication device and an IoT platform and other edge devices within the vehicle. Edge devices include, but are not limited to, tablets, EFBs, and LRUs that are connected to the gateway via Wi-Fi or ethernet, for example. Vehicle data gateway 109 is loosely defined as a component which takes in data from several sources and components, primarily providing the data to an IoT platform. Communication in the E2E framework is comprised of software connectors and software gateway applications, whose orientation is primarily defined by the direction of data streaming.

As depicted, E2E framework 500 includes an edge device 501 configured to communicate with a connector application 505A of an edge manager 503 via either an advanced message queueing protocol (AMQP) communication or an HTTPS communication. Similarly, IoT platform 502 is configured to communicate with connector application 505A via either an advanced message queueing protocol (AMQP) communication or an HTTPS communication.

E2E framework 500 further includes a gateway application 504A which is configured to communicate with connector application 505A via an internal communication mechanism or protocol. Gateway application 504B is additionally configured to communicate with connector application 505B via a custom connection, such as (but not limited to) AND, CAN, ARINC429, WAP, and the like. Any of the communications with connector application 505A or gateway application 504A may be stored in storage 506A.

E2E framework 500 further includes a gateway application 504B of edge agent 507 configured to communicate with connector application 505B via an internal communication mechanism or protocol. Gateway application 504B is additionally configured to communicate with APU-ECU 102 via an internal communication mechanism or protocol. Any of the communications with connector application 505B or gateway application 504B may be stored in storage 506B.

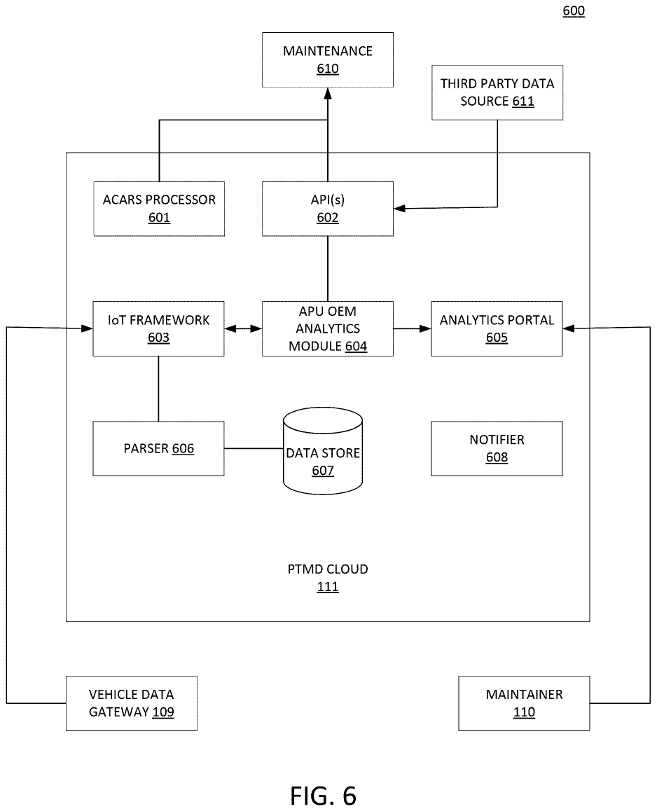

FIG. 6 illustrates a functional block diagram of a cloud environment 600 in accordance with at least some example embodiments of the present disclosure. As depicted, the cloud environment 600 includes components of a PTMD cloud 111 connected to external sources such as maintenance 610, maintainer 110, and vehicle data gateway 109. Cloud environment 600 may enable files/messages to be sent from vehicle data gateway 109 in real-time to applications running in the cloud. Cloud environment 600 may further enable sending commands/files/messages from cloud applications to the vehicle data gateway 109.

Predictive Trend Monitoring and Diagnostics cloud (PTMD cloud 111) may be a cloud-based application configured to analyze APU performance data to provide condition insights corresponding to APU 101. As depicted, PTMD cloud 111 includes ACARS processor 601, APIs 602, IoT framework 603, APU OEM analytics module 604, analytics portal 605, parser 606, data store 607, and notifier 608. ACARS processor 601 is configured to convert messages that are received in real time from a vehicle in a first format, such as ARINC 618, and converts them into a second format, such as ARINC 620, for use by vehicle operations. In at least some embodiments, ACARS processor 601 is configured to convert messages uplinked from an offboard system and vehicle operations in a second format to the vehicle in a third format which can be viewed by the operator.

APIs 602 may be configured to allow software applications to interact with one another. In at least some embodiments, APIs 602 are configured to expose services provided by the applications and components deployed in the cloud. In at least some embodiments, the APIs 602 can be invoked by analytics portal 605 (via a web dashboard, for example), or by other applications. APIs 602 may be configured to invoke external 3^{rd} party APIs if required (such as weather data from 3^{rd} party sources, for example). APIs 602 may also be configured to transfer data to one or more external systems via a push/pull mechanism. In at least some embodiments, APIs 602 may be configured to send data to maintenance 610.

IoT framework 603 may be a framework configured to enable two-way communication between vehicle data gateway 109 and the various components of PTMD cloud 111. In at least some embodiments, IoT framework 603 may be configured to allow messages/commands/files to be sent from the PTMD cloud 111 to vehicle data gateway 109, as well as to allow the vehicle data gateway 109 to send files/messages/telemetry data from the vehicle data gateway 109 to PTMD cloud 111. In at least some embodiments, the commands sent from PTMD cloud 111 to the vehicle data gateway 109 may be acknowledged by the vehicle data gateway 109 with a required response. In at least some embodiments, the vehicle data gateway 109 and the IoT framework 603 are configured to securely communicate over an IP channel (Wi-Fi/Satcom, etc.) through well-defined APIs, such as APIs 602. The protocols used may include, but are not limited to, any of HTTPS, MQTT, AMQP, and the like. In at least some embodiments, IoT framework 603 utilizes digital certificates such as public key infrastructure (PKI) to ensure cybersecurity by allowing only devices with valid certificates to communicate with PTMD cloud 111.

APU OEM analytics module 604 may be configured to perform data analytics on input data received from APU 101 or APU-ECU 102. In at least some embodiments, APU OEM analytics module 604 is configured to use predictive algorithms configured to perform predictive trend monitoring and diagnostics. These algorithms calculate estimated time to failure and optimize maintenance planning. In at least some embodiments, APU OEM analytics module 604 is configured to diagnose, troubleshoot, and pinpoint APU problems to help reduce time to repair. In at least some embodiments, APU OEM analytics module 604 is configured to generate machine learning model files by continuously learning and training on input data received from APU 101 and/or APU-ECU 102. Machine learning models that work on real-time data on the edge node are also generated and subsequently loaded into the vehicle data gateway where edge analytics are performed. In at least some embodiments, APU OEM analytics module 604 is configured to make use of third-party data sources. For example, APU OEM analytics module 604 may be configured to leverage data received from a weather data source to refine its predictions for upcoming trips by the subject vehicle. In at least some embodiments, APU OEM analytics module 604 is configured to send messages to an operator to start APU 101 during vehicle operation as part of periodic checks. In such embodiments, APU OEM analytics module 604 ensures that the APU 101 is only started during travel if a sufficient interval has been crossed from a previous instance of APU 101 operation. APU OEM analytics module 604 may further be configured to run commands from maintainer 110 to run built-in tests or to provide specifically requested data. APU OEM analytics module 604 may be configured to run said commands while the APU-ECU 102 is in maintenance mode to ensure that tests are run only when it is safe to do so.

Analytics portal 605 may be a visual dashboard application configured to provide graphical details of parameter trending. In at least some embodiments, analytics portal 605 is configured to show notifications and generate notifications to be sent to maintainers. In at least some embodiments, such notifications are generated real-time responsive to receiving data from APU 101 via IoT framework 603, and is subsequently processed by APU OEM analytics module 604. Analytics portal 605 may be configured to display results of requested built in tests. Further yet, analytics portal 605 may be configured to retrieve and display requested data.

Parser 606 may be configured to convert input coming in from APU-ECU 102 into a required format. In at least some embodiments, parser 606 converts the incoming input into a preferred format associated with processing by one or more components of PTMD cloud 111.

Data store 607 may be configured to store configuration parameters and parsed and processed data used to populate analytics portal 605. In at least some embodiments, data store 607 is configured to store distribution lists associated with the subject vehicle for sending email/text notifications to users signed up for this feature.

Notifier 608 may be configured to generate notifications in a required format from processed data in data store 607. In at least some embodiments, the generated notifications contain details of faults, thresholds crossing, criticality levels, probabilities, and trend data for various parameters of the APU 101. In general, notifier 608 is configured to provide maintainer 110 to troubleshoot APU issues.

In at least some embodiments, PTMD cloud 111 is configured to send and receive data to any of vehicle data gateway 109 and/or maintainer 110. PTMD cloud 111 may be configured with a machine learning model configured to determine APU 101's condition and/or a predicted future condition of APU 101 based at least in part on historical data corresponding to APU 101 and one or more historically relevant APU measurements for similar APU implementations.

Third-party data source 611 may be an application configured to provide data which may be pertinent to APU performance. As an example, third-party data source 611 may be a source via which PTMD cloud 111 can receive/retrieve weather data. In at least some embodiments, weather data may include incidents of high temperature, low temperature, high humidity, precipitation, snow, wind and dust, sandstorms, altitude, and pressure changes. High ambient temperatures reduce APU efficiency, as the air entering an APU is less dense, thereby making it difficult to compress the air to the necessary combustion level. This can also affect APU performance and cause it to overheat, triggering automatic shutdowns.

High temperature can also lead to increased fuel consumption. The usage of forecast weather data can help predict these occurrences, while also providing specific insights regarding the performance impact of these conditions.

Extreme low temperatures can make it difficult to start an APU due to thickened lubricants and fuel. This may lead to longer startup sequence, causing increased drain on battery and starter motor wear and tear. Further, metal parts contract in the cold, potentially leading to cracks. Freezing temperatures lead to ice formation on APU air intakes and exhaust, restricting airflow.

High humidity contributes to corrosion of metal parts in the APU, potentially degrading components over time. Rain causes water ingestion, damaging internal components, reducing combustion efficiency, and potentially causing compressor stalls or flameouts. Freezing conditions can lead to ice buildup leading to flameouts. Icy conditions may require de-icing before operation, which can be forecast to a maintainer.

Strong crosswinds/tailwinds effect airflow intake leading to stalls and flameouts. Further, dust ingestion can erode compressor blades/seals, thereby degrading performance. Low air pressure and density at high altitude can make it difficult for APU to compress air for efficient operation.

All of the above weather conditions contribute to changes in APU performance. As such, historical data can provide insights regarding time series APU performance data, as anomalous performances may be attributable to various weather conditions which were present at the time the metrics were recorded. Further yet, weather forecast data can provide insights regarding predicted future APU performance.

Maintenance 610 may be an offboard service responsible for tracking and otherwise managing vehicle maintenance. In at least some embodiments, maintenance 610 may be configured to manage roles and responsibilities associated with the maintainer 110 responsible for the state of the vehicle. Maintainer 110 may be a mechanic, maintenance technician, engineer, or other individual responsible for inspecting, repairing, and maintaining vehicles to ensure they are safe for travel. In at least some embodiments, maintainer 110 is representative of a plurality of individuals responsible for vehicle maintenance. In at least some embodiments, maintainer 110 is representative of a system configured to provide information to the individual(s) responsible for maintaining the subject vehicle.

FIG. 7 illustrates a mind map 700 including a data tree of APU malfunctions according to which a machine learning model for performing edge analytics relative to an APU. As depicted, the mind map 700 segments APU malfunctions according to four categories/data tiers. From left to right, the mind map 700 is first segmented according to problem or malfunction type. Example malfunctions include, but are not limited to, fuel supply issues and related LRUs, overheating, sensor and control system failures, air intake and exhaust issues, starting system failures, environmental control system (ECS) failures, electrical system failures and related LRUs, bleed air system issues, mechanical failures, lubrication system failures, hydraulic system failures, fuel quality issues, and the like. The mind map is next segmented according to a corresponding LRU, part, or subsystem of the APU. Example subsystem/part categories include, but are not limited to, the fuel control unit, oil pump and cooling system, turbine/compressor, electronic control unit (ECU), various sensors (temperature, flow, pressure, etc.), air intake system, exhaust system, starter motor, ignition system, air conditioning packs, de-icing system, generator, starter motor, bleed air valve, turbine/compressor assembly, bearings, oil pump, oil filter, hydraulic pump, fuel system, and fuel filter. The mind map is next segmented according to a more specific component of each LRU or subsystem, examples of which include, but are not limited to, a fuel flow sensor, a fuel pressor, fuel pressure sensor, temperature sensor, oil temperature sensor, exhaust gas temperature (EGT) sensor, ambient temperature sensor, turbine inlet temperature sensor, bearing temperature sensor, input/output signal monitors, voltage supply sensor, processing time/delay sensors, built in test data/diagnostics, sensor calibration data, pressure sensor, flow rate sensor, backpressure sensor, current draw sensor, RPM sensor, voltage sensor, timing sensor, current sensor, frequency sensor, RPM fluctuations, noise, oil pressure sensor, oil flow sensor, oil temperature sensor, differential pressure sensor, flow rate sensor, temperature sensor, water detection sensor, and fuel quality sensor. The right-most section of each line of the mind map is directed towards remediating actions associated with the corresponding specific component. In at least some embodiments, the remediating actions are actions which have been historically utilized to remedy issues with the subject specific component. In at least some embodiments, the remediating actions are actions identified according to an inputted manual for maintaining/repairing the subject component(s).

### Example Human Machine Interfaces (HMIs) and Displays of the Disclosure

Having described example systems and apparatuses in accordance with the disclosure, example human machine interfaces and displays will now be discussed. It will be appreciated that each HMI depicts an example interface usable with respect to the apparatuses, systems, devices, and/or computer program products described herein, for example utilizing one or more of the specially configured components thereof.

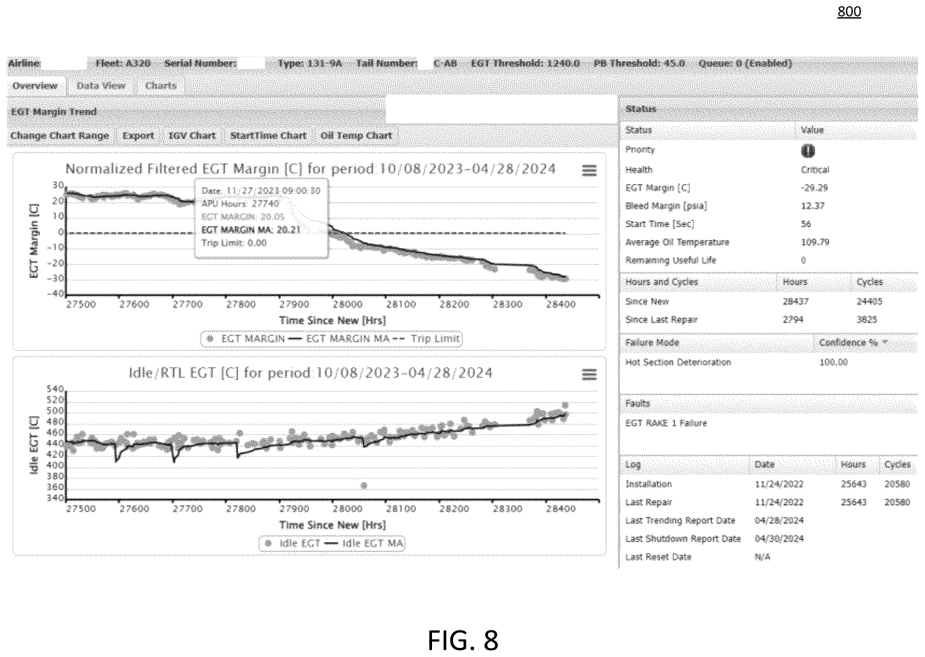

FIG. 8 illustrates an example PTMD dashboard 800 in accordance with at least some example embodiments of the present disclosure. As depicted, PTMD dashboard 800 includes identifying information corresponding to a subject APU, along with time series data corresponding to various depicted APU metrics. Further, the PTMD dashboard 800 includes a priority status indicator, a health indicator, an EGT margin, a bleed margin, a start time, an average oil temperature, a remaining useful life measurement, duration data since new, duration data since a last repair, a failure mode, one or more faults, and a series of repair logs. PTMD dashboard 800 is only an example of an appropriate dashboard for displaying APU data, and it should be appreciated that many variations of the dashboard may be appropriate for displaying the pertinent information. In general, mind map 700 can be used in building the machine learning model for diagnostics.

### Example Processes of the Disclosure

Having described example systems and apparatuses, data architectures, and data flows in accordance with the disclosure, example processes of the disclosure will now be discussed. It will be appreciated that each of the flowcharts depicts an example computer-implemented process that is performable by one or more of the apparatuses, systems, devices, and/or computer program products described herein, for example utilizing one or more of the specially configured components thereof.

The blocks indicate operations of each process. Such operations may be performed in any of a number of ways, including, without limitation, in the order and manner as depicted and described herein. In some embodiments, one or more blocks of any of the processes described herein occur in-between one or more blocks of another process, before one or more blocks of another process, in parallel with one or more blocks of another process, and/or as a sub-process of a second process. Additionally, or alternatively, any of the processes in various embodiments include some or all operational steps described and/or depicted, including one or more optional blocks in some embodiments. With regard to the flowcharts illustrated herein, one or more of the depicted block(s) in some embodiments is/are optional in some, or all, embodiments of the disclosure. Similarly, it should be appreciated that one or more of the operations of each flowchart may be combinable, replaceable, and/or otherwise altered as described herein.

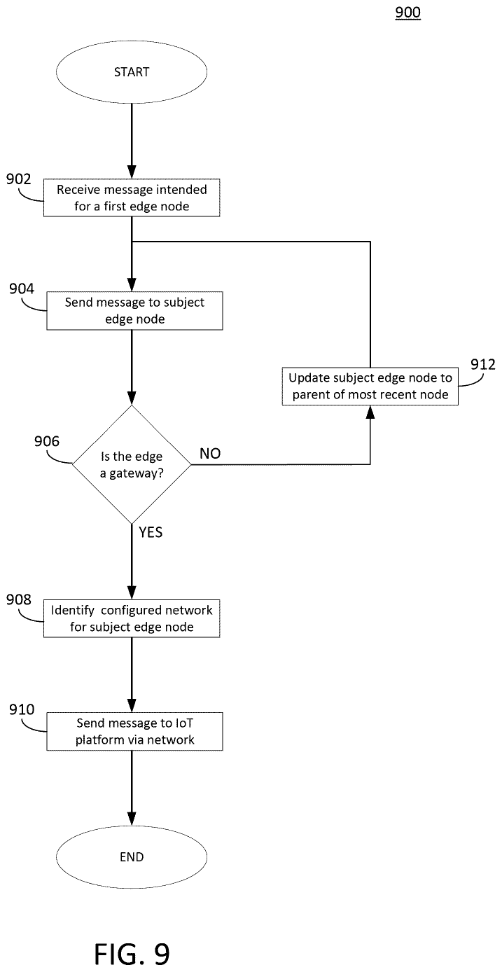

FIG. 9 illustrates a flowchart depicting a process 900 for managing dataflow from APU-ECU 102 to PTMD cloud 111. As depicted, process 900 includes receiving (902) a message intended for a first edge node, sending (904) the message to a subject edge node, determining (906) if the subject edge node is a gateway, identifying (908) a configured network associated with the subject node, sending (910) the message to IoT framework 603 via the configured network, and updating (912) the subject edge node to the parent of a most recent node. Process 900 enables real-time two-way dataflow between APU-ECU 102 and PTMD cloud 111.

At step 902, APU-ECU 102 receives a message intended for a first edge node. Receiving (902) a message intended for a first edge node may include receiving a message, file, or other data item intended for a destination node. In at least some embodiments, receiving (902) a message intended for a first edge node includes receiving the message and an indication of an intended destination component, application, or system.

At step 904, APU-ECU 102 sends the message to a subject node. Sending (904) the message to a subject edge node may include sending the message to the intended first edge node in embodiments where the subject node has not been propagated. In embodiments where the subject node has been propagated to a parent node of a recent node, sending (904) the message to the subject edge node includes sending the message to a parent node (or grandparent node, great grandparent node, etc. upon further iterations) after the subject node has been updated to another member of the first edge node's family tree.

At step 906, APU-ECU 102 determines whether the current subject node corresponds to a vehicle data gateway or an IoT platform. Determining (906) if the subject edge node is a gateway may include determining whether the subject edge node is configured for real-time communication to either a vehicle data gateway or an IoT platform, such as vehicle data gateway 109 and/or IoT framework 603. If the subject edge node is a gateway (step 906, yes branch) APU-ECU 102 proceeds to identify (908) a configured network associated with the subject node. If the subject edge node is not a gateway (step 906, no branch), APU-ECU 102 proceeds to update (912) the subject edge node to a parent of the most recent node.

At step 908, APU-ECU 102 identifies a configured network associated with the subject edge node. Identifying (908) a configured network associated with the subject edge node may include identifying a communication protocol or preferred communication network associated with the subject edge node. In at least some embodiments, the configured network associated with the subject edge node is a network or communication protocol identified by metadata associated with the subject gateway/edge node.

At step 910, APU-ECU 102 sends the message to IoT framework 603 via the configured network. Sending (910) the message to IoT framework 603 via the configured network may include transmitting the message to IoT framework 603 via the preferred communication network/communication protocol. Sending (910) the message to IoT framework 603 may further include receiving confirmation of receipt of the sent message.

At step 912, APU-ECU 102 updates the subject edge node to a parent of the most recent node. Updating (912) the subject edge node to the parent of the most recent node may include, for a first iteration, updating the subject node from the first edge node to a parent of the first edge node. In a second iteration, the subject node is updated from the parent of the first edge node to a grandparent of the first edge node (i.e., a parent of the parent of the first edge node), and so on. Updating (912) the subject edge node ultimately occurs iteratively until a gateway node is reached.

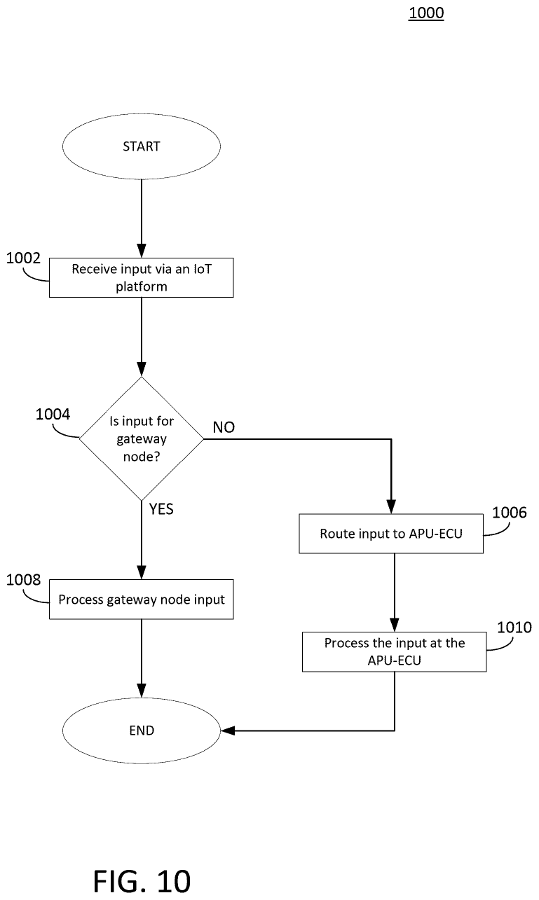

FIG. 10 illustrates a flowchart depicting a process 1000 for managing dataflow from PTMD cloud 111 to APU-ECU 102. As depicted, process 1000 includes receiving (1002) input via an IoT platform, determining (1004) if the received input is intended for a gateway node, routing (1006) the received input to an APU-ECU, processing (1008) the received input, and transmitting (1010) the received input using the APU-ECU. Process 1000 enables real-time two-way dataflow between APU-ECU 102 and PTMD cloud 111.

At step 1002, PTMD cloud 111 receives input via an IoT platform. Receiving (1002) input via an IoT platform may include receiving APU data or input via an IoT platform such as IoT framework 603. In at least some embodiments, receiving (1002) input includes receiving an indication of an intended destination component, application, or system for the input.

At step 1004, PTMD cloud 111 determines if the received input is intended for a gateway node. Determining (1004) if the received input is intended for a gateway node may include determining whether the gateway node is configured for real-time communication to either a vehicle data gateway or an IoT platform, such as vehicle data gateway 109 and/or IoT framework 603. If the received input is intended for a gateway node (step 1004, yes branch) PTMD cloud 111 proceeds to process (1008) the received input. If the received input is not intended for a gateway node (step 1004, no branch), PTMD cloud 111 proceeds to route input to APU-ECU 102.

At step 1006, PTMD cloud 111 routes the received input to APU-ECU 102. Routing (1006) the received input to APU-ECU 102 may include transmitting the received input to APU-ECU 102 using one or more defined communication protocols or preferred communication networks. In general, routing (1006) the received input to APU-ECU 102 includes providing the received input to an APU-ECU 102 which is operably connected to the desired destination node.

At step 1008, PTMD cloud 111 processes the received input. Processing (1008) the received input may include processing the received input to identify subject data, messages, commands, and the like requiring attention. In at least some embodiments, processing (1008) the received input includes providing the data to one or more additional components operably connected to the PTMD cloud 111 for further use and/or processing.

At step 1008, APU-ECU 102 processes the received input. Processing (1010) the received input may include processing the received input to identify subject data, messages, commands, and the like requiring attention. In at least some embodiments, processing (1010) the received input includes providing the data to one or more additional components operably connected to APU-ECU 102 for further use and/or processing.

### Conclusion

Although an example processing system has been described above, implementations of the subject matter and the functional operations described herein can be implemented in other types of digital electronic circuitry, or in computer software, firmware, or hardware, including the structures disclosed in this specification and their structural equivalents, or in combinations of one or more of them.

Embodiments of the subject matter and the operations described herein can be implemented in digital electronic circuitry, or in computer software, firmware, or hardware, including the structures disclosed in this specification and their structural equivalents, or in combinations of one or more of them. Embodiments of the subject matter described herein can be implemented as one or more computer programs, i.e., one or more modules of computer program instructions, encoded on computer storage medium for execution by, or to control the operation of, information/data processing apparatus. Alternatively, or in addition, the program instructions can be encoded on an artificially-generated propagated signal, e.g., a machine-generated electrical, optical, or electromagnetic signal, which is generated to encode information/data for transmission to suitable receiver apparatus for execution by an information/data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially-generated propagated signal. The computer storage medium can also be, or be included in, one or more separate physical components or media (e.g., multiple CDs, disks, or other storage devices).

The operations described herein can be implemented as operations performed by an information/data processing apparatus on information/data stored on one or more computer-readable storage devices or received from other sources.

The term “data processing apparatus” encompasses all kinds of apparatus, devices, and machines for processing data, including by way of example a programmable processor, a computer, a system on a chip, or multiple ones, or combinations, of the foregoing. The apparatus can include special purpose logic circuitry, e.g., an FPGA (field programmable gate array) or an ASIC (application-specific integrated circuit). The apparatus can also include, in addition to hardware, code that creates an execution environment for the computer program in question, e.g., code that constitutes processor firmware, a protocol stack, a repository management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, script, or code) can be written in any form of programming language, including compiled or interpreted languages, declarative or procedural languages, and it can be deployed in any form, including as a stand-alone program or as a module, component, subroutine, object, or other unit suitable for use in a computing environment. A computer program may, but need not, correspond to a file in a file system. A program can be stored in a portion of a file that holds other programs or information/data (e.g., one or more scripts stored in a markup language document), in a single file dedicated to the program in question, or in multiple coordinated files (e.g., files that store one or more modules, sub-programs, or portions of code). A computer program can be deployed to be executed on one computer or on multiple computers that are located at one site or distributed across multiple sites and interconnected by a communication network.

The processes and logic flows described herein can be performed by one or more programmable processors executing one or more computer programs to perform actions by operating on input information/data and generating output. Processors suitable for the execution of a computer program include, by way of example, both general and special purpose microprocessors, and any one or more processors of any kind of digital computer. Generally, a processor will receive instructions and information/data from a read-only memory or a random-access memory or both. The essential elements of a computer are a processor for performing actions in accordance with instructions and one or more memory devices for storing instructions and data. Generally, a computer will also include, or be operatively coupled to receive information/data from or transfer information/data to, or both, one or more mass storage devices for storing data, e.g., magnetic, magneto-optical disks, or optical disks. However, a computer need not have such devices. Devices suitable for storing computer program instructions and information/data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described herein can be implemented on a computer having a display device, e.g., a CRT (cathode ray tube) or LCD (liquid crystal display) monitor, for displaying information/data to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

Embodiments of the subject matter described herein can be implemented in a computing system that includes a back-end component, e.g., as an information/data server, or that includes a middleware component, e.g., an application server, or that includes a front-end component, e.g., a client computer having a graphical user interface or a web browser through which a user can interact with an implementation of the subject matter described herein, or any combination of one or more such back-end, middleware, or front-end components. The components of the system can be interconnected by any form or medium of digital information/data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

The computing system can include clients and servers. A client and server are generally remote from each other and typically interact through a communication network. The relationship of client and server arises by virtue of computer programs running on the respective computers and having a client-server relationship to each other. In some embodiments, a server transmits information/data (e.g., an HTML page) to a client device (e.g., for purposes of displaying information/data to and receiving user input from a user interacting with the client device). Information/data generated at the client device (e.g., a result of the user interaction) can be received from the client device at the server.

In some embodiments, some of the operations above may be modified or further amplified. Furthermore, in some embodiments, additional optional operations may be included. Modifications, amplifications, or additions to the operations above may be performed in any order and in any combination.

Many modifications and other embodiments of the disclosure set forth herein will come to mind to one skilled in the art to which this disclosure pertains having the benefit of the teachings presented in the foregoing description and the associated drawings. Therefore, it is to be understood that the embodiments are not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

While this specification contains many specific implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain implementations, multitasking and parallel processing may be advantageous.

What is claimed is:

1. A system for two-way auxiliary power unit analysis, the system comprising:
an auxiliary power unit electronic control unit (APU-ECU) configured to:
monitor performance of an auxiliary power unit, and
provide a set of auxiliary power unit performance metrics;
a vehicle data gateway (VDG) system comprising:
a communication interface configured for data transfer between the VDG system and the APU-ECU,
a data aggregator configured to collect data from subsystems of a subject vehicle and prepare said data for one or more intended uses,
an electronic information management connector configured to enable secure communication between the VDG system and an electronic information management device for the subject vehicle,
a cloud connector configured to enable secure communication between the VDG system and a cloud system via a secured connection, and
a system command module configured to receive and interpret commands from one or more external devices, and subsequently invoke an interface of a corresponding auxiliary power unit; and
an edge-to-edge framework configured to facilitate secure communication between the VDG system and the APU-ECU, wherein the edge-to-edge framework provides details about resident software modules, communication protocols, and security provisions between the APU-ECU and the VDG system.

2. The system of claim 1, wherein the data aggregator is configured to data for transmission to one or more external systems.

3. The system of claim 1, wherein the edge-to-edge framework defines a framework comprising software connectors and software gateway applications whose orientation is primarily defined by a direction of data streaming.

4. The system of claim 1, further comprising an auxiliary power unit (APU) analytics module configured for performing data analytics on input data received from the auxiliary power unit.

5. The system of claim 4, wherein the APU analytics module is configured to use one or more predictive models for predictive trend monitoring and diagnostics to troubleshoot and diagnose APU errors.

6. The system of claim 5, wherein the APU analytics module is configured to continuously train the one or more predictive models based on data received from the auxiliary power unit.

7. The system of claim 1, further comprising an analytics portal comprising a visual dashboard application providing graphical details of parameter trending.

8. The system of claim 1, wherein the APU-ECU is configured to:
receive a message intended for a first edge node;
send the message to the first edge node;
determine if the first edge node is a gateway node;
responsive to determining that the first edge node is a gateway node, identify a configured network associated with the first edge node; and
send the message to an Internet of Things (IoT) platform via the configured network.

9. The system of claim 8, wherein the APU-ECU using the edge-to-edge framework is configured to:
responsive to determining that the first edge node is not a gateway node, select a parent node of the first edge node;
determine if the parent node of the first edge node is a gateway node;
responsive to determining that the parent node of the first edge node is a gateway node, identify a configured network associated with the parent node of the first edge node; and
send the message to the IoT platform via the configured network.

10. The system of claim 1, wherein the cloud system comprises an Internet of Things (IoT) platform configured to:
receive input intended for a subject edge node;
determine if the subject edge node is a gateway node; and
responsive to determining that the subject edge node is a gateway node, process the received input.

11. The system of claim 10, wherein the IoT platform is further configured to:
responsive to determining that the subject edge node is not a gateway node, route the received input to the APU-ECU.

12. The system of claim 11, wherein the APU-ECU is further configured to:
process the received input using the APU-ECU responsive to determining that the subject edge node is not a gateway node.

13. A computer-implemented method comprising:
receiving, by an auxiliary power unit electric control unit (APU-ECU), a message intended for a first edge node;
sending, by the APU-ECU, the message to the first edge node;
determining, by the APU-ECU, if the first edge node is a gateway node;
responsive to determining that the first edge node is a gateway node, identifying, by the APU-ECU, a configured network associated with the first edge node; and
transmitting, by the APU-ECU, the message to an Internet of Things (IoT) platform via the configured network.

14. The computer-implemented method of claim 13, further comprising:
responsive to determining that the first edge node is not a gateway node, selecting a parent node of the first edge node;
determine if the parent node of the first edge node is a gateway node;
responsive to determining that the parent node of the first edge node is a gateway node, identify a configured network associated with the parent node of the first edge node; and
sending the message to the IoT platform via the configured network.

15. The computer-implemented method of claim 14, further comprising:
transmitting, by the IoT platform, the received message to an additional node to which the IoT platform is operably connected.

16. The computer-implemented method of claim 13, further comprising:
receiving, by the IoT platform, input intended for a subject edge node;
determining, by the IoT platform, if the subject edge node is a gateway node; and
responsive to determining that the subject edge node is a gateway node, transmitting, by the IoT platform and to the subject edge node, the received input.

17. The computer-implemented method of claim 16, further comprising:
responsive to determining that the subject edge node is not a gateway node, transmitting, by the IoT platform and to the APU-ECU, the received input.

18. The computer-implemented method of claim 17, further comprising:
transmitting, by the APU-ECU, the received input to the subject edge node.

19. A computer program product comprising at least one non-transitory computer-readable storage medium having computer program code stored thereon that, in execution with at least one processor, is configured to execute operations comprising:
receiving, by an auxiliary power unit electric control unit (APU-ECU), a message intended for a first edge node;
sending, by the APU-ECU using an edge-to-edge framework, the message to the first edge node;
determining, aby the APU-ECU, if the first edge node is a gateway node;
responsive to determining that the first edge node is a gateway node, identifying, by the APU-ECU, a configured network associated with the first edge node; and
transmitting, by the APU-ECU, the message to an Internet of Things (IoT) platform via the configured network.

20. The computer program product of claim 19, the computer program code that, in execution with at least one processor, is further configured to execute operations comprising:
receiving, by the IoT platform, input intended for a subject edge node,
determining, by the IoT platform, if the subject edge node is a gateway node; and
responsive to determining that the subject edge node is a gateway node, transmitting, by the IoT platform and to the subject edge node, the received input.
